(19) United States
(12) Patent Application Publication
(10) Pub. No.: US 2002/0098648 A1
(43) Pub. Date: Jul. 25, 2002

(54) Method for fabricating a nonvolatile semiconductor memory cell

(76) Inventors: Christoph Ludwig, Langebruck (DE); Martin Schrems, Eggersdorf (AT)

Correspondence Address: LERNER AND GREENBERG, P.A., Post Office Box 2480, Hollywood, FL, 33022-2480, US

(21) Appl. No.: 10/013,264

(22) Filed: Apr. 4, 2002

Related U.S. Application Data
(63) Continuation of application No. PCT/DE00/01898, filed on Jun. 9, 2000.

(30) Foreign Application Priority Data
Jun. 10, 1999 (DE) 199 26 500.3

(51) Int. Cl. H01L 21/336

(52) U.S. Cl. 438/257

(57) ABSTRACT

A method for producing a nonvolatile semiconductor memory cell, that includes producing a floating gate in a self-aligning manner using standard processes. The use of TiO₂ or WOₓ as the dielectric layer between the control gate and the floating gate results in a sufficiently high capacitive coupling factor, so that it is possible to fabricate a semiconductor memory cell of very small dimensions.

### CROSS-REFERENCE TO RELATED APPLICATION

This application is a continuation of copending International Application No. PCT/DE00/01898, filed Jun. 9, 2000, which designated the United States.

### BACKGROUND OF THE INVENTION

1. Field of the Invention

The present invention relates to a method for fabricating a nonvolatile semiconductor memory cell, in particular a semiconductor memory cell that is used in a EPROM (Electrically Programmable Read Only Memory), a EEPROM (Electrically Erasable Programmable Read Only Memory), or a FLASH-EPROM.

Nonvolatile memories, such as for example EPROMs, EEPROMs and FLASH-EPROMs, are generally known. Nonvolatile memories of this type usually include a large number of transistors which operate as memory cells. Each memory includes a source region and a drain region, which are formed on the surface of a semiconductor substrate. On the surface of the semiconductor substrate there is usually an insulating layer, on which a floating gate is formed in order to store charges. Above the floating gate there is a control gate, which is separated from the floating gate by a further insulating layer.

To store an item of logic information, either a small number or a large number of charges are stored in the floating gate and influence the switching behavior of the channel region or FET (Field Effect Transistor) below it. Since the value of the data stored in the floating gate represents a function of the charge level stored therein, a loss of charge in the floating gate may change the information that is stored in the memory cell. Therefore, for a nonvolatile memory cell to function, it is extremely important for the charges stored in the floating gate to be retained for a long time.

These properties for the retention of charges are determined in particular by the insulating layers that surround the floating gate. To prevent a loss of charge, the insulating layers must have a high breakdown voltage. If, for example, during a programming operation a high voltage is applied to the control gate, the insulating layer must have a sufficiently high breakdown voltage to prevent electrons from flowing from the floating gate to the control gate.

On the other hand, after the charges have been introduced into the floating gate, the insulating layer has to sufficiently prevent a leakage current out of the floating gate. Leakage currents of this type are usually produced through pin holes and other defects in the insulating layer. Therefore, it is extremely important for the insulating layer to have a uniform structure with a low number of pin holes.

A range of methods, such as for example injection of hot charge carriers, channel injection, and Fowler-Nordheim tunneling, are known for the purpose of transferring the charges to the floating gate. In all of these methods, the control voltage which has to be applied to the control gate to write, read, and erase the charges to/from the floating gate is a function of the capacitance between the floating gate and the control gate, and is therefore, dependent on the thickness of the corresponding insulating layer. To reduce the control voltage which is required for programming or introducing charges into the floating gate, it has been proposed, for example, to reduce the thickness of the insulating layer.

However, if the thickness of the dielectric layer is reduced, the storage capacity of the floating gate deteriorates because of the leakage currents that occur via the pin holes and other defects in the insulating layer.

Conventional semiconductor memory cells and associated methods for their fabrication therefore, use an oxide/nitride/oxide (ONO) layer as the insulating layer between the floating gate and the control gate. This has the advantage that there is virtually no possibility of a leakage current being caused by dislocations or defects in the insulating layer.

FIGS. 4a to 4h show a conventional method for fabricating a conventional semiconductor memory cell on a semiconductor substrate. As shown in FIG. 4a, first of all a semiconductor substrate 1 is coated with a photoresist 2 and is exposed via a mask M. In a subsequent etching step (STI process), as shown in FIG. 4b, shallow isolation trenches are uncovered between active regions. After the remaining photoresist 2 has been removed, the entire surface of the semiconductor substrate 1 is covered with an SiO₂ layer as a field oxide layer 3. FIG. 4d shows the result of the subsequent planarization step that is performed such that the surface of the semiconductor substrate 1 is uncovered at the active regions. In a following step, as shown in FIG. 4e, a tunnel oxide layer 4, a first conductive layer 5, and a further photoresist 2 are applied to the semiconductor substrate 1 and the field oxide 3, and are exposed via a further mask M. In the step shown in FIG. 4f, the first conductive layer 5, which has been patterned in accordance with FIG. 4e is etched, with the result that floating-gate tracks are formed that have a larger surface area than the channel layer. Then, as shown in FIGS. 4g and 4h, a second insulating layer 6 and a second conductive layer 7 are applied, and in a further patterning and etching step (not shown), a further etching step is carried out in order to form control-gate tracks.

FIG. 5 shows a perspective view of a conventional semiconductor memory cell which has been fabricated in this manner. The control-gate tracks which have been fabricated from the second conductive layer 7 are consequently separated from one another by a trench, in which in each case, one source connection S and one drain connection (not shown) are formed. The control-gate connection D is situated on the surface of the second conductive layer 7. This results in a multiplicity of semiconductor memory cells which are arranged in the form of a matrix. The surface area of the floating gate FG is a multiple of the surface area of the channel layer below it, in order to provide the capacitive coupling that is required for the introduction of charges via the first insulating layer 4.

However, a drawback of this conventional semiconductor memory cell and of the associated fabrication method is that a large number of patterning steps with corresponding etching steps are required, which is both expensive and time-consuming. Furthermore, only a low integration density is possible because the size of the floating gate FG is larger than that of the channel layer.

To improve the integration density and to reduce the control voltages required, U.S. Pat. No. 5,739,566 discloses a semiconductor memory cell in which the floating gate includes two floating-gate layers that are spaced apart from one another and that are connected to one another via a floating-gate contact. Although the integration density can be increased in this way, in combination with reduced control voltages, this conventional method is extremely complex and is therefore, expensive.

### SUMMARY OF THE INVENTION

It is accordingly an object of the invention to provide a method of fabricating a nonvolatile semiconductor memory cell which overcomes the above-mentioned disadvantages of the prior art methods of this general type.

In particular, it is an object of the invention to provide a method for fabricating the memory cell on a semiconductor substrate, in which, using a standard process, further improvement of the integration density and a reduction of the control voltages required for the memory cell are ensured.

With the foregoing and other objects in view there is provided, in accordance with the invention, a method for fabricating a nonvolatile semiconductor memory cell on a semiconductor substrate, that includes steps of: providing a semiconductor substrate having a surface; forming a first dielectric layer, which has a first relative dielectric constant εᵣ₁, on the semiconductor substrate; forming a first conductive layer on the first dielectric layer; self-aligning etching the first conductive layer, the first dielectric layer, and part of the surface of the semiconductor substrate to form a patterned surface with floating-gate tracks; forming a field oxide layer on the patterned surface; planarizing the field oxide layer and uncovering the first conductive layer; forming a second dielectric layer, having a second relative dielectric constant εᵣ₂ that is greater than the first relative dielectric constant εᵣ₁, on the planarized field oxide layer and the first conductive layer; forming a second conductive layer on the second dielectric layer; etching the second conductive layer, the second dielectric layer and the first conductive layer to form a patterned surface with control-gate tracks and floating-gate regions; and performing the step of forming the second dielectric layer by forming a metal-containing layer and then converting the metal-containing layer into a metal oxide layer using thermal oxidation.

In accordance with an added feature of the invention, the field oxide layer and the first dielectric layer consist of SiO₂ and act as etching stop layers.

In accordance with an additional feature of the invention, the second dielectric layer is either TiO₂ and WOₓ, where x=2 to 3.

In accordance with another feature of the invention, the step of forming the field oxide layer is performed by depositing the field oxide layer using a TEOS process.

Particularly because of the self-aligning etching step, in which the first conductive layer together with the first dielectric layer and a part of the surface of the semiconductor substrate is removed, in combination with the fact that a material is used for the second dielectric layer whose relative dielectric constant is higher than that of the first dielectric layer, it is possible to fabricate a functioning semiconductor memory cell with extremely small dimensions using a standard process.

Preferably, a field oxide layer and the first dielectric layer consist of SiO₂ which, in conjunction with a corresponding etchant, act as etching stop layers, with the result that during the formation of control-gate tracks, it is at the same time possible to partition floating gates. In this way, expensive and time-consuming patterning steps with the associated provision of corresponding masks are eliminated.

The second dielectric layer preferably consists of WOₓ and/or TiO₂, which as insulating materials have a high relative dielectric constant and provide a coupling factor that is sufficient to write/erase and read the information stored in the floating gate.

Other features which are considered as characteristic for the invention are set forth in the appended claims.

Although the invention is illustrated and described herein as embodied in a method for fabricating a nonvolatile semiconductor memory cell, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIGS. 1a to 1f show diagrammatic sectional views illustrating the steps used to fabricate an inventive semiconductor memory cell;

FIG. 2 shows a perspective view of the inventive semiconductor memory cell;

FIG. 3 shows another perspective view of the semiconductor memory cell, which has been bisected in the sectional plane A/A′-B/B′ shown in FIG. 2;

FIGS. 4a to 4h are diagrammatic sectional views illustrating the steps involved in fabricating a conventional semiconductor memory cell; and

FIG. 5 shows a perspective view of the conventional semiconductor memory cell.

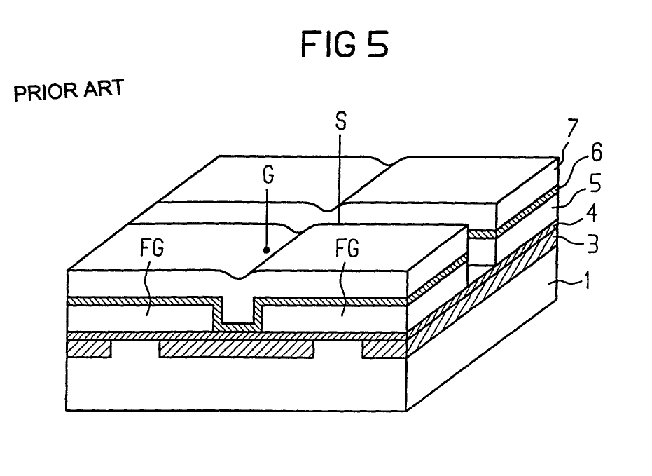

### DESCRIPTION OF THE PREFERRED EMBODIMENTS

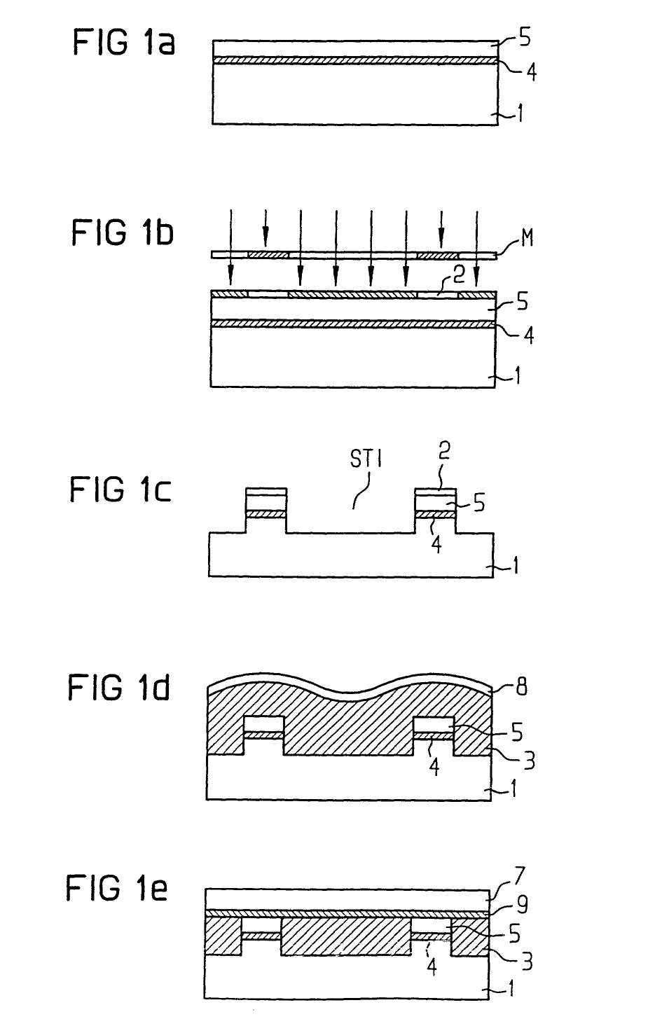

Referring now to the figures of the drawing in detail and first, particularly, to FIGS. 1a-1f thereof, there is shown diagrammatic sectional views illustrating the respective method steps involved in fabricating a preferred exemplary embodiment of an inventive semiconductor memory cell. As shown in FIG. 1a, first of all a semiconductor substrate 1 is provided, preferably consisting of Si, SiGe, SiC, SOI, GaAs or another III-V semiconductor. In a subsequent thermal oxidation process, a first dielectric layer 4 with a small thickness is formed at a temperature of approximately 900 to 1050° C. The dielectric layer 4 preferably consists of thermally produced SiO₂ with a thickness of approximately 8 to 13 nm. This first dielectric layer 4 is also referred to as the tunnel oxide, since in particular, tunneling effects are responsible for the introduction of charges through this first dielectric layer 4.

Then, a thin first conductive layer 5, which forms the subsequent floating gate, is formed on the first dielectric layer 4. The thickness of the first conductive layer 5 is as thin as possible, at approximately 80 nm. The first conductive layer 5 preferably consists of a doped polysilicon layer which is formed, for example, by means of a conventional LPCVD (Low Pressure Chemical Vapor Deposition) method.

In this way, as shown in FIG. 1a, the layers for the tunnel oxide and the floating gate are already provided in a particularly simple way using standard processes.

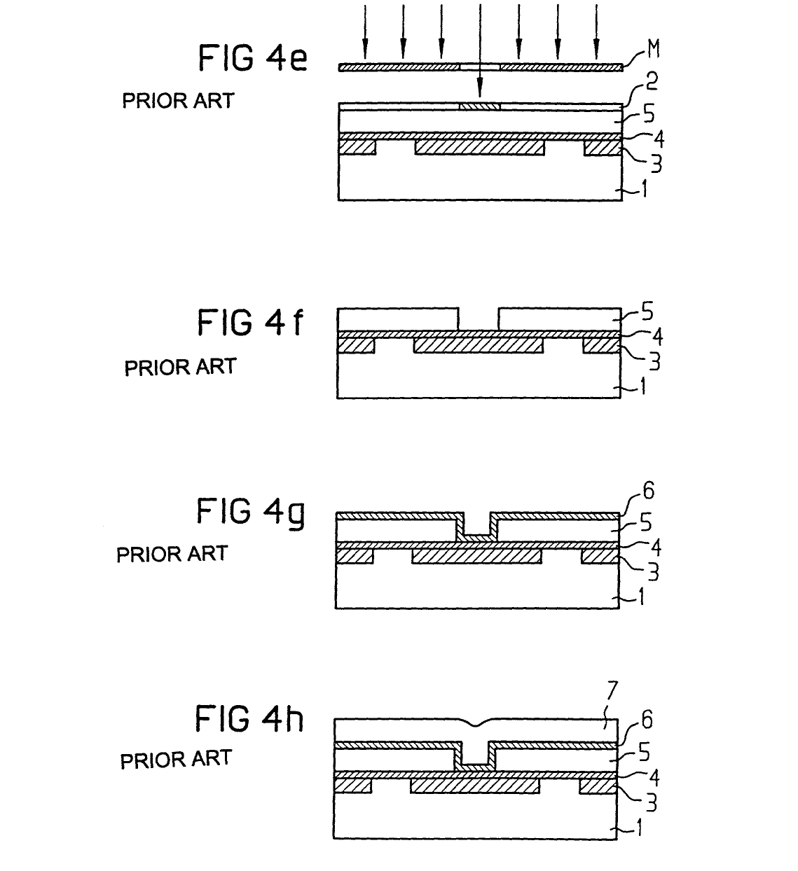

In the method step shown in FIG. 1b, a first patterning is then carried out using a mask M and a photosensitive layer (photoresist) 2 that has been applied to the first conductive layer 5. In this step, in a similar way to the conventional method step shown in FIG. 4b, the active regions of the subsequent semiconductor memory cell are established. In the process, the photoresist 2 is initially exposed via a mask M, and then the exposed photoresist 2 is developed and removed, so that an anisotropic etching step can subsequently be carried out. As shown in FIG. 1c, it is preferable to use an STI (shallow trench isolation) process for this purpose, during which, a part of the semiconductor substrate 1 is etched away. The method step shown in FIG. 1c therefore corresponds to a self-aligning fabrication step for both the first conductive layer 5 (floating gate) and the first dielectric layer 4 below it, as well as the channel region (not shown) below that. Unlike in the conventional method, a patterning step and the provision of a further mask M have already been avoided at this point.

In the method step shown in FIG. 1c, it is preferable to employ anisotropic reactive ion etching (RIE), in which the semiconductor substrate 1 is etched down to a depth of approximately 250 nm to 400 nm.

In the following method step shown in FIG. 1d, a field oxide layer 3 is deposited or (selectively) grown over the entire surface that has been formed in this manner. This field oxide layer completely covers the layer stack including the silicon substrate 1, the first dielectric layer 4, and the first conductive layer 5. The field oxide layer 3 preferably consists of SiO₂ and is deposited in a TEOS process at a temperature of approximately 450 to 600° C. After the field oxide layer 3 has been deposited, it is partially removed in a planarizing step and is leveled with the surface of the first conductive layer 5.

To improve this planarizing step it is optionally possible for a further conductive layer 8, which preferably consists of polysilicon, to be formed on the field oxide layer 3.

Then, a second dielectric layer 9 is formed over the entire planarized surface of the silicon wafer. This second dielectric layer 9 covers both the field oxide layer 3 and the first conductive layer 5 and forms an insulating layer between a floating gate and a control gate. To form the control gate, a second conductive layer 7 is formed on the second dielectric layer 9, and is then patterned and etched to form longitudinal tracks.

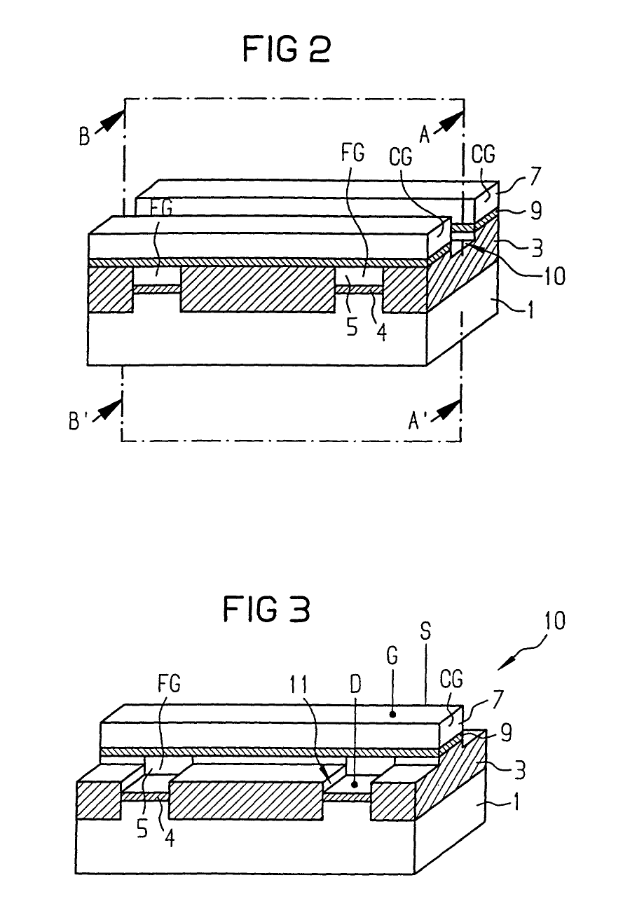

FIG. 2 shows a perspective view of the inventive semiconductor memory cell. Accordingly, the second conductive layer 7 is etched to form a multiplicity of control-gate tracks CG which lie perpendicular to the floating-gate tracks FG and divide them into individual floating-gate regions.

Particularly when using SiO₂ for the first dielectric layer 4 and the field oxide layer 3, the SiO₂, in conjunction with a suitable etchant, acts as an etching stop layer, with the result that during etching of the control-gate tracks CG, individual floating-gate regions are formed in a self-aligning manner beneath the control-gate tracks CG.

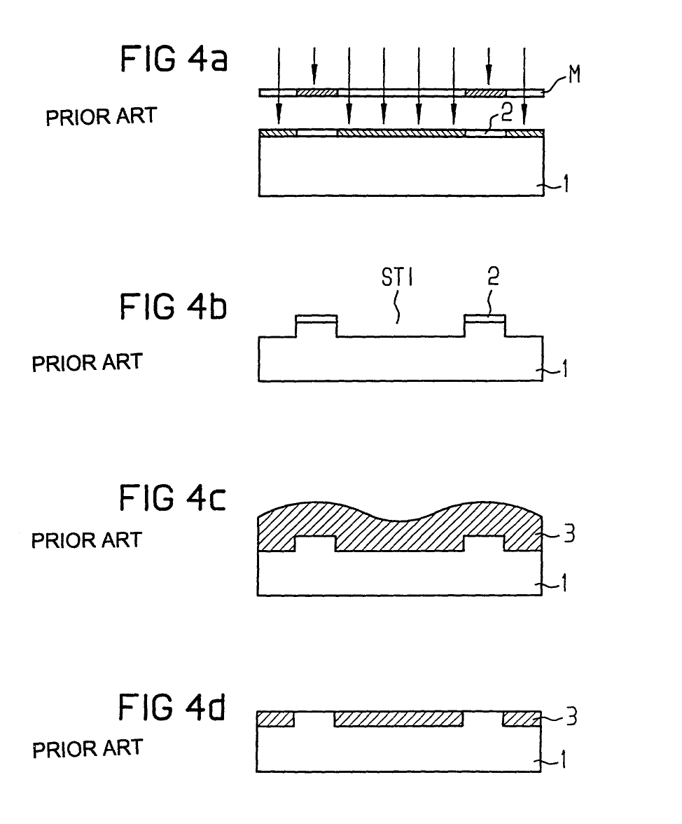

FIG. 3 shows a perspective view illustrating this automatically produced structure in a sectional plane A/A′-B/B′ in accordance with FIG. 2.

In this way, a semiconductor memory cell is fabricated using standard processes, which, in particular on account of the self-aligning method step, requires an extremely small amount of space to form a floating gate, and the cell is therefore suitable for a high integration density. Moreover, the method steps allow the self-aligned contact technique to be implemented. In this case, the space taken up for each cell is reduced further.

As has already been described above, however, a semiconductor memory cell of this type, when conventional materials (e.g. ONO) are used for the second dielectric layer 9, is only able to function with very high control voltages, since the capacitive coupling factor between the control gate CG and the floating gate FG is not sufficient to, for example, write or erase the floating gate FG with charges by injection of hot charge carriers, channel injection or Fowler-Nordheim tunneling. Instead of the conventional oxide/nitride/oxide (ONO layer), the present invention therefore uses a special second dielectric layer 9 with a relative dielectric constant εᵣ₂ which is higher than the dielectric constant εᵣ₁ of the first dielectric layer. More specifically, the present invention uses a layer with an extremely high relative dielectric constant εᵣ₂ for the second dielectric layer 9, with the occurrence of pin holes also being avoided.

Surprisingly, TiO₂ or WOₓ, where x=2 to 3, which on the one hand allow excellent coupling factors of the control gate CG to the floating gate, FG and furthermore, allow sufficient charge retention in the floating gate FG, have proven to be suitable materials of this type for the second dielectric layer 9.

The way in which the second dielectric layer 9 is formed is described in detail below for WOₓ and TiO₂.

I. Forming a WOₓ Layer:

To form the second dielectric layer 9 as WOₓ, first of all a tungsten-containing layer, such as for example a pure tungsten layer, a tungsten nitride layer or a tungsten silicide layer, is applied. The tungsten-containing layer is produced, for example, using a sputtering process (PVD method) or a CVD method.

If a CVD method is used, a variety of methods can be employed:

CVD of W (On Silicon, Not Selective):

e.g. WF₆+SiH₄→W+gases (seed layer)

e.g. WF₆+H₂→W+gases (bulk layer)

CVD of W (On Silicon, Selective with Respect to Nitride, oxide):

e.g. 2WF₆3 Si→2 W+3 (SiF₄)

e.g. WF₆+H₂→W+gases

CVD of WSiₓ:

e.g. WF₆+SiH₂Cl₂→Wsiₓ (e.g.: x=2 to 3)+gases

CVD of WN (Tungsten Nitride, e.g. W₂N):

e.g. 4WF₆+N₂+12H₂ (plasma CVD)→4 W₂N+24 (HF)

(e.g. at a temperature of 350-400° C.)

The layer thickness of the tungsten-containing layer produced in this way is approximately 10 to 20 nm. Then, the tungsten-containing layer is converted into a tungsten oxide layer, which corresponds to the second dielectric layer 9, by thermal oxidation. The conversion takes place in an oxygen atmosphere (for example O₂ or H₂O) at a temperature of 500 to 1200° C. When using a pure tungsten layer or a tungsten silicide layer, the temperature should not exceed approximately 600° C. In other words a low thermal budget RTO (rapid thermal oxidation) should be carried out, in order to prevent silicon from diffusing into the tungsten-containing layer and preventing oxidation of the tungsten-containing layer.

The thermal oxidation of the tungsten-containing layer leads to a second dielectric layer (tungsten oxide layer) 9 which contains hardly any impurities and has a relative dielectric constant εᵣ of greater than 50. The layers and process parameters are in this case preferably selected in such a way that the tungsten-containing layer is completely converted into the tungsten oxide layer or into the second dielectric layer 9. Then, as has already been described above, the second conductive layer 7 is formed on the tungsten oxide layer or second dielectric layer 9. In a similar manner to the first conductive layer 5, the second conductive layer may also consist of polysilicon.

When using silicon for the first conductive layer 5, it is also possible for a tungsten oxide layer to be applied directly as the second dielectric layer 9. This tungsten oxide layer can be produced, for example, using a CVD method. For this purpose, tungsten fluoride and water in the gaseous state are passed as precursors onto the planarized surface:

2WF₆+4 H₂O→(WOF₄)+WO₃+(HF) or

WF₆+H₂O+Si→W−O+(2 HF)+(SiF₄)

This leads to the deposition of a tungsten oxide layer in a thickness of approximately 2 to 20 nm as second dielectric layer 9.

Using a subsequent heat treatment at a temperature of approximately 550 to 1100° C. in an inert atmosphere, the tungsten oxide layer can be produced in a crystalline or sintered phase (for example phases with an orthorhombic or tetragonal symmetry). This heat treatment may take place immediately after the tungsten oxide layer has been produced or may only take place in a subsequent process step once the second conductive layer 7 for the control gate CG has already been applied.

II. Forming a Titanium Dioxide Layer:

As an alternative to the tungsten oxide layer described above, it is also possible to use a titanium dioxide layer for the second dielectric layer 9. In this case, first of all a titanium layer is deposited on the surface, for example using a sputtering process, such that the layer thickness is approximately 6-50 nm. The thickness of this titanium layer is preferably 20 nm, allowing resistance to leakage currents and the use of oxygen plasma etching at 200-300° C.

Then, the titanium layer is converted into a titanium dioxide layer, which forms the second dielectric layer 9, by thermal oxidation. The conversion takes place in an oxygen atmosphere at approximately 600° C. The thermal oxidation of the titanium layer leads to a very pure, stoichiometric titanium dioxide layer that contains hardly any impurities. Moreover, during the thermal oxidation, oxygen atoms are drawn out of the surface into the metal layer, so that any silicon dioxide layer which forms on the surface of the second conductive layer 5 is completely removed during the thermal oxidation of the titanium dioxide layer 9. The result is a very clean boundary surface between the first conductive layer 5 for the floating gate and the titanium dioxide layer, which forms the second dielectric layer 9. This has positive effects in particular with a view to avoiding the leakage currents described in the introduction, with the result that the charges introduced into the floating gate FG can be retained particularly well.

By means of subsequent conditioning at approximately 900° C., it is possible to produce a titanium dioxide layer in the rutile phase. This conditioning may take place during the production of the titanium dioxide layer. However, it may also only be carried out in a subsequent process step after the second conductive layer 7 has been formed.

The relative dielectric constant εᵣ₂ of the titanium dioxide layer (TiO₂) produced in this way is accordingly higher than the relative dielectric constant εᵣ₁ of the first dielectric layer, with the result that a capacitive coupling factor for the control gate to the floating gate, which is sufficiently high for information to be written, read and erased to/from the memory cell via the small area when low control voltages are applied, is produced.

We claim:

1. A method for fabricating a nonvolatile semiconductor memory cell on a semiconductor substrate, which comprises:
providing a semiconductor substrate having a surface;
forming a first dielectric layer, which has a first relative dielectric constant εᵣ₁, on the semiconductor substrate;
forming a first conductive layer on the first dielectric layer;
self-aligning etching the first conductive layer, the first dielectric layer, and part of the surface of the semiconductor substrate to form a patterned surface with floating-gate tracks;
forming a field oxide layer on the patterned surface;
planarizing the field oxide layer and uncovering the first conductive layer;
forming a second dielectric layer, having a second relative dielectric constant εᵣ₂ that is greater than the first relative dielectric constant εᵣ₁, on the planarized field oxide layer and the first conductive layer;
forming a second conductive layer on the second dielectric layer;
etching the second conductive layer, the second dielectric layer and the first conductive layer to form a patterned surface with control-gate tracks and floating-gate regions; and
performing the step of forming the second dielectric layer by forming a metal-containing layer and then converting the metal-containing layer into a metal oxide layer using thermal oxidation.

2. The method according to claim 1, wherein the field oxide layer and the first dielectric layer consist of SiO₂ and act as etching stop layers.

3. The method according to claim 2, which comprises forming the second dielectric layer from a material selected from the group consisting of TiO₂ and WOₓ, where x=2 to 3.

4. The method according to claim 1, which comprises forming the second dielectric layer from a material selected from the group consisting of TiO₂ and WOₓ, where x=2 to 3.

5. The method according to claim 1, which comprises performing the step of forming the field oxide layer by depositing the field oxide layer using a TEOS process.
